(19) United States
(12) Patent Application Publication
(10) Pub. No.: US 2006/0290689 A1
(43) Pub. Date: Dec. 28, 2006

(54) Semiconductor half-bridge module with low inductance

(76) Inventors: William Grant, Fountain Valley, CA (US); Heny Lin, Irvine, CA (US); Jack Marcinkowski, San Pedro, CA (US); Velimir Nedic, Los Angeles, CA (US)

Correspondence Address: OSTROLENK FABER GERB & SOFFEN, 1180 AVENUE OF THE AMERICAS, NEW YORK, NY, 100368403, US

(21) Appl. No.: 11/474,714

(22) Filed: Jun. 26, 2006

Related U.S. Application Data
(60) Provisional application No. 60/693,678, filed on Jun. 24, 2005.

(51) Int. Cl. G09G 5/00; H01L 29/76

(52) U.S. Cl. 345/204; 257/343; 257/734; 361/637

(57) ABSTRACT

A power module that includes embedded power bus bars and output bus arranged to lower the parasitic inductance.

### RELATED APPLICATION

This application is based on and claims the benefit of U.S. Provisional Application Ser. No. 60/193,678, filed on Jun. 24, 2005, entitled Semiconductor Switch Half-Bridge Module with Low Inductance, to which a claim of priority is hereby made and the disclosure of which is incorporated by reference.

### FIELD OF THE INVENTION

The invention relates to power modules and more particularly to half-bridge power modules.

### BACKGROUND OF THE INVENTION

It is well known that power modules such as semiconductor half-bridge modules can be used in power applications such as power conversion and/or power supply. Conventional modules are built by assembling and connecting semiconductor die with wirebonds or the like to a lead frame and terminals for external connection. The die are usually mounted on a conductive metallic layer bonded to a nonconductive substrate, and the lead frame is usually insert-molded into a plastic enclosure. Thus, the current is carried by the wirebonds, the metallic layer of the substrate and the lead frame. Conductive terminals accessible from the outside make it possible to connect the module to an external circuit but very often the standard DC terminals are far apart and exhibit high parasitic inductance.

Minimizing the parasitic inductance is crucial in all switch-mode power conversion applications. If parasitic inductance is not minimized the transient voltage overshoots and losses of the semiconductor die are increased, effectively reducing the amount of power the semiconductor die are able to process.

### SUMMARY OF THE INVENTION

A power module according to the present invention includes a frame, a first bus connectable to one pole of a power source and embedded within the frame, a second bus connectable to another pole of a power source and embedded within the frame, an output bus embedded within the frame and spaced vertically from but disposed opposite to the first and the second bus bars, and a power circuit including a high side power semiconductor switch and a low side power semiconductor switch, the high side power semiconductor switch being electrically connected to the first bus and the output bus, and the low side power semiconductor switch being electrically connected to the second bus and the output bus.

In the preferred embodiment, the frame is molded out of a suitable plastic.

A module according to the present invention further includes a first substrate integrated with the frame and a second substrate integrated with the frame, wherein the high side power semiconductor switch is disposed on the first substrate and the low side power semiconductor switch is disposed on the second substrate. Preferably, the first substrate is disposed lateral to the first bus, the second bus and the output bus, and the second substrate is disposed lateral to the first bus, the second bus, and the output bus and opposite the first substrate, whereby the first bus, the second bus and the output bus are disposed between the first substrate, and the second substrate.

In the preferred embodiment, the first substrate includes a common gate track for all the high side switches and the second substrate includes a common gate track for all the low side switches. Furthermore, the first substrate includes an emitter sense track for all the high side switches and the second substrate includes an emitter sense track for all the low side switches. In addition, the high side switches share a common collector pad on the first substrate, and the low side switches share a common collector pad on the second substrate.

A module according to the present invention also includes a collector sense lead electrically connected to the common collector pad on the first substrate, a collector sense lead electrically connected to the common collector pad on the second substrate and a plurality of high side I/O leads for the high side power semiconductor switch integrated with the frame, and a plurality of low side I/O leads for the low side power semiconductor switch integrated with the frame, wherein the I/O leads include a temperature sense lead, collector sense lead, an emitter sense lead and gate lead.

Other features and advantages of the present invention will become apparent from the following description of the invention which refers to the accompanying drawings.

### BRIEF DESCRIPTION OF THE DRAWINGS

FIG. 1 illustrates a half-bridge circuit according to the preferred embodiment of the present invention.

FIG. 2A shows a top plan view of a housing arrangement in a power module according to the present invention.

FIG. 2B shows a cross-sectional view of the housing arrangement along line 2B-2B viewed in the direction of the arrows.

FIG. 3 shows a top plan view of a power module according to the preferred embodiment.

### DETAILED DESCRIPTION OF THE FIGURES

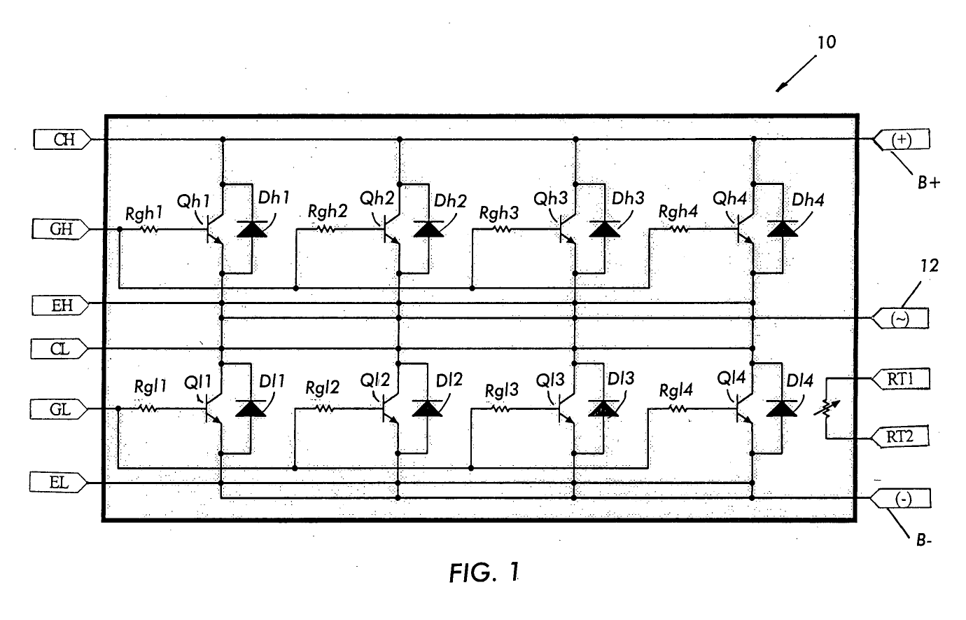

Referring to FIG. 1, a power module according to the preferred embodiment of the present invention includes a single phase half-bridge circuit 10, which preferably includes four parallel-connected high side MOS-gated semiconductor switches Qh₁, Qh₂, Qh₃, Qh₄, and a plurality of parallel connected low side MOS-gated semiconductor switches Ql₁, Ql₂, Ql₃, Ql₄. Note that preferably a power diode Dh₁, Dh₂, Dh₃, Dh₄, Dl₁, Dl₂, Dl₃, Dl₄ is connected in parallel with a respective power switch. As is conventionally known, high side switches are connected to one power terminal (e.g. B+terminal) at one power electrode thereof, while the low side switches are connected to the other power terminal (e.g. B−, or ground) at one power electrode thereof. The high side switches and the low side switches are series connected to form a half bridge having an output node 12 at the point of connection of the high side and the low side switches.

In the preferred embodiment, IGBTs are used in the half bridge circuit 10. Thus, high side IGBTs are connected to the B+ terminal at the collector electrode thereof, low side IGBTs are connected to the B− terminal at the emitter electrode thereof, and the emitter electrode at each high side switch is connected to the collector electrode of a respective low side switch. Note that in the preferred embodiment, circuit 10 would include a single high side gate terminal GH, and a single low side gate terminal GL in that the gates of high side IGBTs and the gates of the low side IGBTs are parallel connected and receive a single gate signal from either terminal GH (high side IGBTs) or terminal GL (low side IGBTs). Preferably, circuit 10 would further include terminals for collecting information. For example, circuit 10 includes two terminals RT1, RT2 for collecting information regarding the temperature of the power switches, a terminal EL for collecting low side emitter current, a terminal CH for collecting high side collector current, a terminal EH for collecting high side emitter current, and a terminal CL for collecting low side collector current.

Note that although IGBTs are preferred, other power semiconductor devices, such as power MOSFETs, or III-nitride based power devices, may be used in circuit 10 without deviating from the invention.

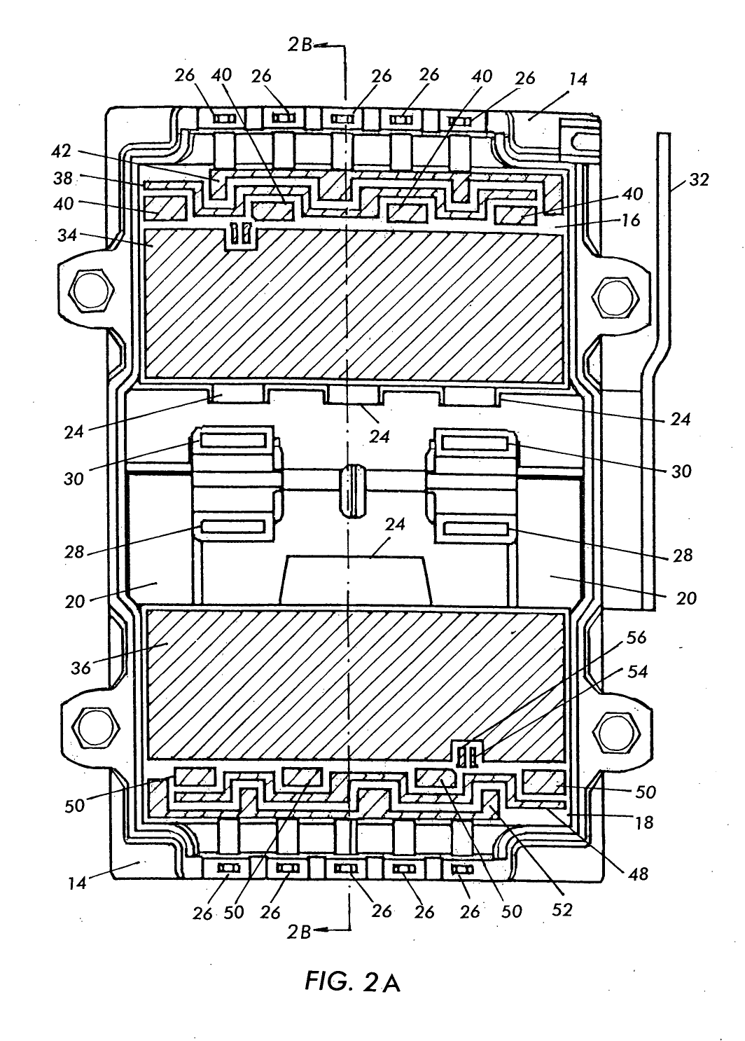

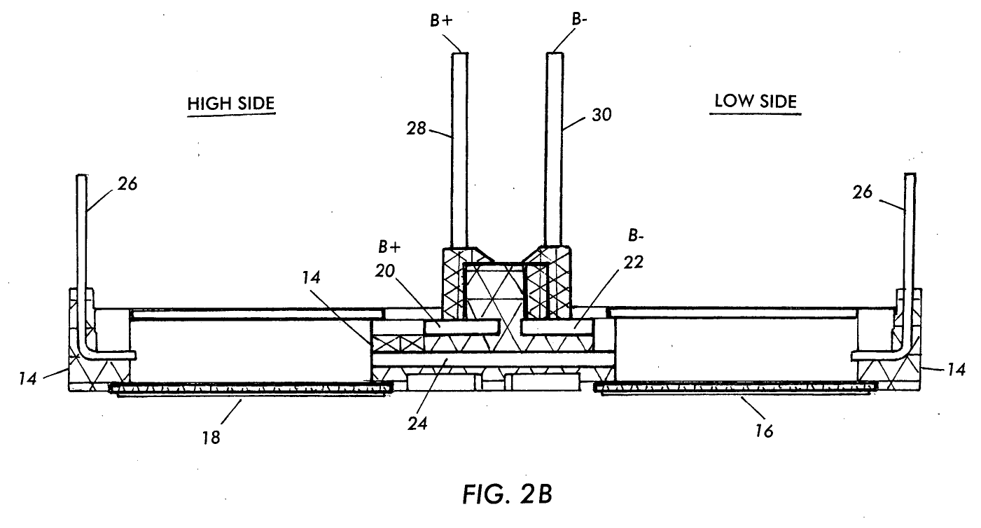

Referring next to FIG. 2A, and 2B, a power module according to the present invention includes a housing arrangement which includes a molded frame 14, first and second substrates 16, 18, B+ bus bar 20, B− bus bar 22, output bus bar 24, and a plurality of input/output (I/O) leads 26. B+ bus bar 20, B− bus bar 22, output bus bar 24, and leads 26 are embedded (molded in) frame 14. Note that output bus bar 24 is spaced vertically from but disposed opposite to B+ bus bar 20 and, B− bus bar 22, and thus B+, B− bus bars 20, 22 are on one plane and output bus bar 24 is on another plane. Furthermore, substrates 16, and 18 are either molded in or otherwise attached to frame 14 by an adhesive or the like. Note that preferably frame 14 is generally shaped like the numeral eight, thus having two opposing openings across a central region in which B+ bus bar 20 B− bus bar 22, and output bus bar 24 reside. Each substrate 16, 18 closes a respective opening as shown in the Figures. Note that each B+ bus 20, B− bus 22, and output bus 24 includes a respective lead 28, 30, 32. Lead 28 is connectable to a B+ pole of a power source, lead 30 is connectable to the B− pole of the power source, and lead 32 is connectable to the load, which may be preferably a motor. Substrate 16 includes a conductive pad 34 for electrically and mechanically receiving (by a conductive adhesive such as solder or the like) the collector electrodes of the low side IGBTs, and the node electrodes of high side diodes, while substrate 18 includes conductive pad 36 for electrically and mechanically receiving (by a conductive adhesive such as solder or the like) the collector electrodes of the high side IGBTs, and the cathode electrodes of the high side diodes. Substrate 16 includes also low side gate track 38, low side gate pads 40, low side emitter sense track 42, and first 44 and second 46 low side temperature pads. Similarly, substrate 18 includes high side gate track 48, high side gate pads 50, high side emitter sense track 52, and first 54, and second 56 temperature pads 56.

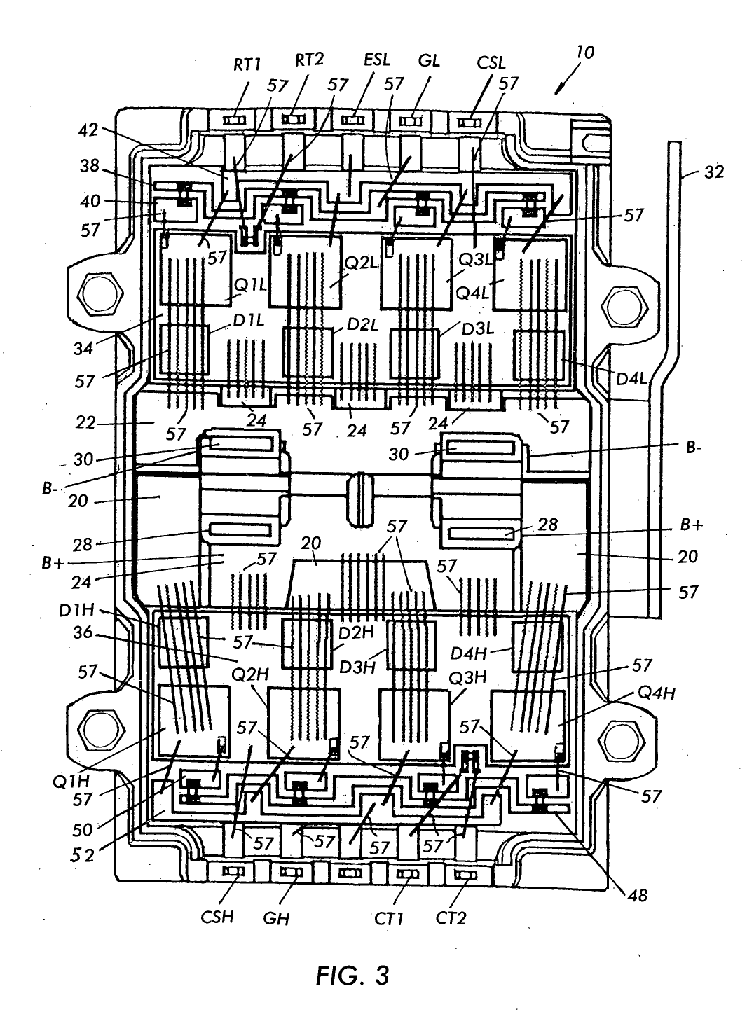

Referring now to FIG. 3, high side switches, high side diodes, low side switches and low side diodes are disposed inside the housing arrangement as shown and interconnected by wirebonds to form circuit 10. Thus, emitters of high side switches and collectors of low side switches are wirebonded to output bus 24, high side collectors are wirebonded to B+ bus 20, the gate of each switch is wirebonded to a respective gate pad 40, 50, and each gate pad is wirebonded to a respective gate track 38, 48. Similarly, leads RT₁, RT₂ of the high side and the low side are wirebonded to temperature sense pads 44, 46, 54, 56, high side and low side gate leads GH, GL are wirebonded to respective gate tracks 48, 38, each high side and low side emitter sense leads ESH, ESL is wirebonded to a respected emitter sense track 52, 42, and each of high side and low side collector sense leads CSH, CSL is connected to a respective conductive pad 36, 34. Note wirebonds are schematically illustrated and identified by numeral 57. Note that the emitter of each IGBT is wirebonded with at least one wirebond to a respective emitter sense track 42, 52.

A power module according to the preferred embodiment includes generally two main integrated parts: frame 14 that includes the copper insert molded lead-frame, and the substrates.

Preferably, frame 14 is made from a suitable molding plastic. A suitable plastic could be PBT, PPS, PPA, or the like, depending on the desired temperature rating for frame 14.

The lead frame as referred to herein includes B+ bus bar 20, B− bus bar 22, output bus bar 24, and I/O leads 26. B+ bus bar 20, B− bus bar 22, output bus bar 24 can be made from copper as thick as 1 mm or more, while I/O leads 26 can be made from copper that is less than 1 mm.

Each substrate 16,18 can be an Insulated Metal Substrate (IMS), Direct Bonded Copper (DBC), Copper on Silicon Nitride, or the like, depending on the desired thermal performance of the module. The IGBTs can be attached to the conductive pads of the substrate using solder or thermally conductive adhesive.

In the preferred embodiment, substrates 16,18 are glued to the housing using an adhesive, and aluminum wires of typically 0.015″ or 0.020″ diameter are used in wirebonding. After the wirebonding operation, silicone gel or the like is deposited over the substrate to protect the diodes and the switches.

A power module according to the present invention minimizes the parasitic inductances of the module. Specifically, according to an aspect of the present invention B+ bus bar 20 and B− bus bar 22 are disposed laterally, side-by-side, and parallel to one another and output bus bar 24 is disposed below B+ bus bar 20 and B− bus bar 22. Due to the arrangement of output bus bar 24 below B+ bus bar 20 and B− bus bar 22 parasitic inductance is reduced. That is, the positioning of the B+ bus bar 20 and its adjacent B− bus bar 22 above output bus bar 24 yields a low inductance module. The symmetrical design of I/O leads 26 and the lay out of substrates 16 and 18 further enhance the low inductance of the module.

Furthermore, advantageously, inductance is evenly distributed between the low side and the high side resulting in a symmetrical electrical circuit. That is, the low side and the high side switches are thus exposed to similar effects of the parasitic inductance such as voltage overshoots and switching stresses. As a result, all the semiconductor switches in the module can be operated at their maximum rating, thereby eliminating the need to reduce the power processing capability of the module to the level of the most stressed switch.

Moreover, having an integrated bus bar eliminates the need for external high inductance interconnects. As a result, the overall stray inductance of the system is effectively reduced enhancing the AC dynamic voltage equalization and allowing for optimal utilization of the voltage blocking capability of the die. Further, since the B+ bus bar 20 and B− bus bar 22 are optimized for the lowest stray inductance and placed close to each other, the positive and negative current paths have the same length, which improves flux cancellation and minimizes the stray fields that would generate EMI noise. In addition, lowering the inductance and symmetrically distributing the inductance between the low and high side reduces the stresses on the semiconductor switches by lowering the voltage overshoots and losses in the semiconductors, thereby effectively reducing radiated EMI noise.

The current capacity of existing modules is usually limited by the current carrying capacity of the metallic layer of the substrate and the wirebonds. A module according to the present invention exhibits improved current capacity by minimizing the use of metallic layer of the substrate for current conduction, minimizing the length of the wirebonds, making the maximum use of the lead frame to conduct high currents, and by providing redundant current paths.

In addition, the sharing of current and switching losses are improved by equalizing the parasitic impedances of the control and power terminals of the semiconductor switches as a result of a symmetrical and balanced construction.

A module according to the present invention having advantageously low parasitic inductance can be combined with a snubber and EMI capacitors, and temperature sensors. Preferably, the capacitors are connected very close to the switches to attain minimum parasitic inductance between the capacitors and the switches, and are most effective in reducing unwanted voltage overshoots, ringing and EMI. The mounting of temperature sensors directly on the substrate next to the semiconductor switches allows monitoring of the semiconductor device thermal conditions for protection purposes.

A module according to the present invention improves the overall efficiency of the motor drive system by allowing increased bus voltage operation and better bus utilization. The permanent-magnet synchronous and induction motor exhibit increased efficiency at higher line voltages. A module according to the present invention enables lower transient over-voltages to allow operation at the increased bus voltage, which results in improved efficiency of the drive system due to the more efficient motor operation.

Although the preferred embodiment of the invention includes a single half-bridge, the concept embodied therein can be used to build full-bridge modules as well as two and three-phase and multi-phase modules.

A power module according to the present invention can be used in all kinds of power conversion applications, for example, DC-DC converters such as Buck, Boost, Buck-Boost, and the like, or AC applications including, for example, single-phase and multi-phase inverters, cyclo-converters, motor drives, etc. The applications may also include switch-mode power amplifiers.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A power module comprising:
a frame;
a first bus connectable to one pole of a power source and embedded within said frame;
a second bus connectable to another pole of a power source and embedded within said frame;
an output bus embedded within said frame and spaced from but disposed opposite to said first and said second bus bars; and
a power circuit including a high side power semiconductor switch and a low side power semiconductor switch, said high side power semiconductor switch being electrically connected to said first bus and said output bus, and said low side power semiconductor switch being electrically connected to said second bus and said output bus.

2. The module of claim 1, wherein said frame is molded.

3. The module of claim 1, wherein first and said second bus bars are on one plane and said output bus is on another plane below said one plane.

4. The module of claim 1, further comprising a first substrate integrated with said frame and a second substrate integrated with said frame, wherein said high side power semiconductor switch is disposed on said first substrate and said low side power semiconductor switch is disposed on said second substrate.

5. The module of claim 4, wherein said first substrate is disposed lateral to said first bus, said second bus and said output bus, and said second substrate is disposed lateral to said first bus, said second bus, and said output bus and opposite said first substrate, whereby said first bus, said second bus and said output bus are disposed between said first substrate, and said second substrate.

6. The module of claim 1, further comprising a high side diode parallel connected with said high side power semiconductor switch and a low side diode parallel connected with said low side power semiconductor switch.

7. The module of claim 1, wherein said power circuit further includes a plurality of high side power semiconductor switches parallel connected with said high side power semiconductor switch, and a plurality of low side power semiconductor switches parallel connected with said low side power semiconductor switch.

8. The module of claim 7, wherein said plurality of high side power semiconductor switches includes three switches and said plurality of low side power semiconductor switches includes three switches.

9. The module of claim 7, further comprising a diode parallel connected with each said high side switch and each said low side switch.

10. The module of claim 7, wherein said first substrate includes a common gate track for all said high side switches and said second substrate includes a common gate track for all said low side switches.

11. The module of claim 7, wherein said first substrate includes an emitter sense track for all said high side switches and said second substrate includes an emitter sense track for all said low side switches.

12. The module of claim 7, wherein said high side switches share a common collector pad on said first substrate, and said low side switches share a common collector pad on said second substrate.

13. The module of claim 12, further comprising a collector sense lead electrically connected to said common collector pad on said first substrate, and a collector sense lead electrically connected to said common collector pad on said second substrate.

14. The module of claim 1, further comprising a plurality of high side I/O leads for said high side power semiconductor switch integrated with said frame, and a plurality of low side I/O leads for said low side power semiconductor switch integrated with said frame, wherein said I/O leads include a temperature sense lead, collector sense lead, an emitter sense lead and gate lead.

15. The module of claim 7, further comprising a plurality of high side I/O leads for said high side power semiconductor switches integrated with said frame, and a plurality of low side I/O leads for said low side power semiconductor switches integrated with said frame, wherein said I/O leads include a temperature sense lead, collector sense lead, an emitter sense lead and gate lead.

16. The module of claim 4, wherein said first substrate and said second substrate each is an IMS, or a DBC.

17. The module of claim 1, wherein said high side and said low side power semiconductor switches are IGBTs, or power MOSFETs.

18. The module of claim 7, wherein said high side and said low side power semiconductor switches are IGBTs, or power MOSFETs.

19. The module of claim 1, wherein said first bus and said second bus are disposed laterally, side-by-side, and parallel to one another and said output bus is disposed below said first bus and said second bus.
